(19) United States
(12) Patent Application Publication
(10) Pub. No.: US 2015/0097261 A1
(43) Pub. Date: Apr. 9, 2015

(54) INTERCONNECT SYSTEM

(71) Applicant: James M. Harris, Palo Alto, CA (US)

(72) Inventor: James M. Harris, Palo Alto, CA (US)

(21) Appl. No.: 14/506,183

(22) Filed: Oct. 3, 2014

Related U.S. Application Data
(60) Provisional application No. 61/887,145, filed on Oct. 4, 2013.

(51) Int. Cl. H01L 23/532; H01L 29/872; H01L 29/45

(52) U.S. Cl. CPC H01L 23/53276; H01L 29/45; H01L 29/872; H01L 23/53209
USPC 257/486; 257/750

(57) ABSTRACT

An electrical contact and electrical interconnect network comprising graphene and a transition metal for a solid state device and an interconnect network for a circuit board or substrate are disclosed.

### PRIORITY

This application claims priority form U.S. Ser. No. 61/887,145; filed on Oct. 4, 2013; incorporated herein in its entirety.

### BACKGROUND OF THE INVENTION

1. Field of Invention

The invention relates generally to solid state device manufacturing processes and associated packaging techniques. In particular, the invention relates to improved methods of forming an electrical contact to a semiconductor, forming an electrical interconnect network and a method for patterning an interconnect network on a circuit board or substrate.

2. Description of Background Art

A critical step in the manufacture of all solid state devices is making electrical contact to a semiconductor surface and/or electrical conductor providing electrical continuity between various components. Current practice in state-of-the-art devices is to use a copper metallization system. Copper is deleterious to semiconductor functionality and must be prevented from migrating to a semiconductor. Current practices involve many additional steps to enable the use of a copper interconnect, including passivation layers as thick as copper metallization layers and the appropriate CMP removal steps as required in a damascene process for multiple metal layers; note U.S. Pat. No. 8,368,053 for description of typical metallization steps and an alternative way of incorporating graphene into an IC The instant invention discloses a novel metallization system not requiring the use of copper with improved conductivity and electromigration properties.

Additional background information is found in U.S. Pat. No. 8,368,053; U.S. 2012/0181510 fails to describe a graphene deposition process other than “transfer”; also note the failure to take proper precautions when using copper metallization; U.S. 2013/0015581 requires a barrier layer underneath a graphene layer; U.S. 2013/0032777; U.S. 2013/0069041; U.S. 2013/0082235; U.S. 2013/0203222; U.S. 2013/0203246; U.S. 2013/0217222; LEE, YOUNGBIN, et al.; “Graphene-based Transparent Conductive Films”; Nano, Vol. 8, No.3 (2013) 1330001; BARINGHAUS, JENS; “Exceptional ballistic transport in epitaxial graphene nanoribbons”; arXiv:1301.5354v2 [cond-mat.mes-hall] 2013; M Xue, H Qiu, W Guo—arXiv:1309.0322, 2013—arxiv.org and WACHTLER, THOMAS; “Thin Films of Copper Oxide and Copper Grown by Atomic Layer Deposition”; Ph.D. thesis; 2010-25 May; Technischen Universitat Chemnitz; all incorporated herein in their entirety by reference.

### BRIEF SUMMARY OF THE INVENTION

Invention resides in the unique design of a process for making a high conductivity electrical contact to a semiconductor or other metallization system wherein no barrier layer is required between the contact metallization and the semiconductor surface; optionally, a barrier layer may be used. The novel contact metallization and interconnect system comprises a contact transition metal layer and a layer of graphene, Cg. The reason a barrier layer is optional is that copper, gold or other high conductivity deleterious metals are replaced by a layer of graphene, Cg, and not needed in the contact metallization structure to achieve high electrical conductivity.

### BRIEF DESCRIPTION OF THE DRAWINGS

FIG. 1 is an example of the prior art showing multilayer copper metallization.

FIG. 2 is a schematic of one embodiment of the invention showing a graphene, Cg, layer above a contact transition metal layer.

FIG. 3 is a schematic of an alternate embodiment showing a graphene, Cg, layer above a contact transition metal layer and a second metal layer atop the Cg layer.

FIG. 4 is a schematic of an alternative embodiment showing a graphene, Cg, layer above a contact transition metal layer, a second contact transition metal layer atop the first Cg layer, a second Cg layer and a third metal layer atop the second Cg layer.

### DETAILED DESCRIPTION OF THE INVENTION

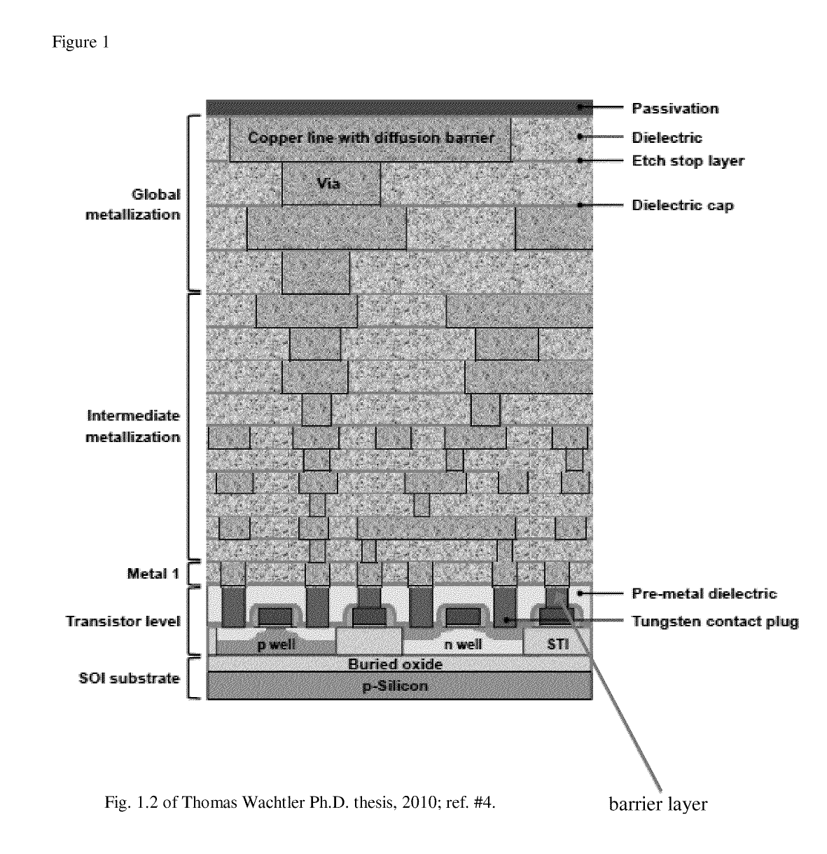

One embodiment of the instant invention relates to forming electrical contact to a semiconductor surface using a “contact transition metal”. Currently a silicide and/or barrier layer must be formed in a via to prevent migration of copper into the semiconductor; as shown in FIG. 1. In some embodiments a barrier layer is not required in the instant invention. In the case of Si, Ge or Si/Ge contact to a semiconductor is made through the use of a transition metal such as Ti, Cr, Co, Ni, Pd, Ta, W, Os, Ir, and Pt; these metals can also serve as a catalytically enhanced surface for deposition of a graphene, Cg, film or layer. As one knowledgeable in the art knows not all transition metals are functional with all Group II, III, IV, V and VI semiconductors; one must select specific transition metals for specific semiconductors or specific semiconductor groupings; a transition metal grouping specific to a predetermined class of semiconductors is termed “contact transition metal(s)”. In some embodiments a thin transition layer-carbide layer is placed between the transition layer and a graphene, Cg, film or layer; this carbide layer enhances the growth properties of a graphene, Cg, film or layer.

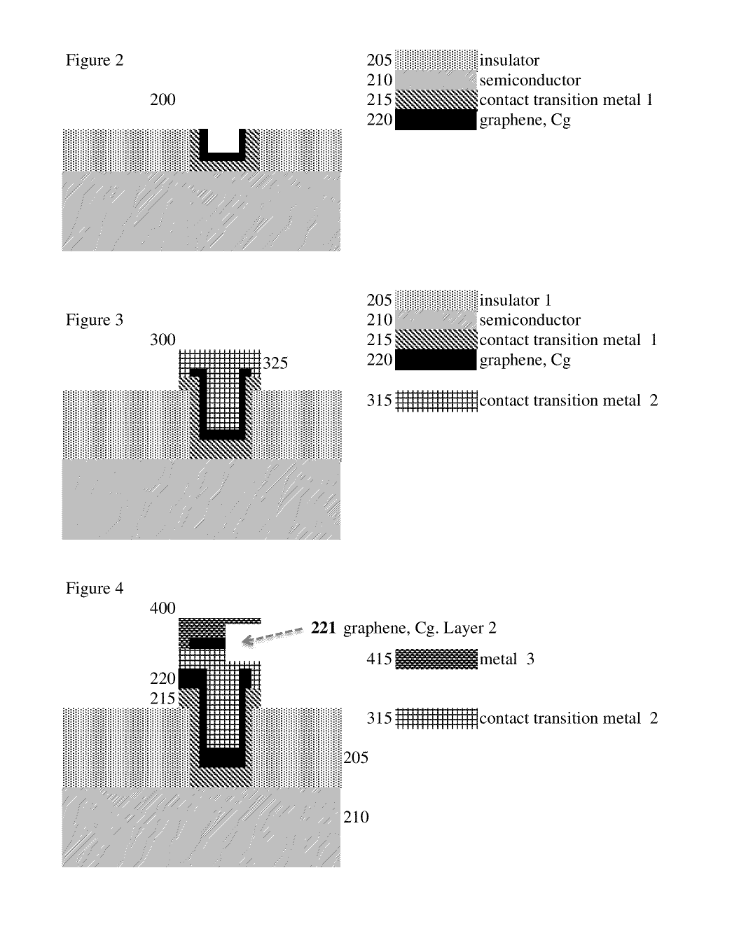

As shown in FIG. 2, in one embodiment of the instant invention a nickel layer 215 may be formed directly in the contact via, and on the side walls of the via; optionally a thin layer of chromium, not shown, may precede the nickel layer to enhance adhesion; optionally the Cr/Ni structure may be annealed; optionally, the structure is annealed during a deposition step for graphene, Cg, 220, at elevated temperature. A second deposition of nickel 315 over the Cg may be done; note FIG. 3; optionally Cr/Ni may be deposited over the Cg to form a “conductive sandwich”; optionally, multiple layers of Cr/Ni/Cg/Cr/Ni/Cg/Cr/Ni may be deposited to form a suitable high current interconnect spanning an entire integrated circuit. In some embodiments a nickel, or Cr/Ni, layer is patterned before deposition of a Cg layer such that the Cg is preferentially deposited only on the nickel surface. Multi-layers of interconnects are constructed in the standard manner. As noted in FIG. 4, “metal 3” 415 may or may not be a transition metal depending upon whether or not graphene, Cg, layers are needed in additional processing. Damascene type processing may not be necessary depending upon configuration of devices 200, 300 and 400. As noted in FIG. 4, a “conductive graphene sandwich” may need to be only about 5 to 10 nm depending upon current requirements. Not shown is the use of a barrier layer in structures 200, 300 and 400 when copper is the preferred transition metal on Si and/or Ge devices.

In some embodiments conventional tungsten contact metallurgy is used and then a contact transition metal used above the tungsten to enable graphene, Cg, conductors for

However thick passivation between layers may not be required; the thickness required for a Cg layer versus a copper interconnect is considerably less. In addition vias and contact dimensions can be reduced appropriately. Ni and Cr/Ni are acceptable for Group III, IV and V semiconductor combinations. Optionally, other combinations of transition metals are used for alternative Group II, III, IV, V and VI solid state devices.

In some embodiments a first contact transition metal 215 may be used to make contact with a semiconductor and a second contact transition metal 315 may be used as a seed layer for a Cg layer. Alternatively a first and second contact transition metal layer may be the same and a third contact transition metal 415, optionally not a transition metal, may be used to construct a conductor sandwich or interconnect sandwich. For example, Pt may be used in the contact vias and, optionally, as a seed layer for the contact construction; then nickel or other, non-transition material, such as aluminum, used in the formation of long interconnect networks. In some embodiments a contact transition metal layer is patterned before subsequent deposition of a Cg layer; optionally a contact transition metal layer is patterned after subsequent deposition of a Cg layer or after deposition of multiple contact transition metal/Cg layers, e.g. a conductor sandwich.

Note in FIG. 3 contact transition metal 2, shown as portion 325, is patterned such that it “encases” around the end and/or side regions of Cg layer 220; similarly for metal 3, 415. In FIG. 4 metal 3 is patterned such that it “encases” around only one end and/or side region of Cg layer 2, 221. In some embodiments this feature is critical to reduce the resistance associated with contacting a Cg layer; optionally, only a portion of a Cg layer need be “encased”.

In some embodiments a substrate is a printed circuit board or ceramic or flexible organic film. In these cases maximum temperature exposure will determine preferred deposition processes for an interconnect. Copper may be a seed metal of choice. Graphene, Cg, may be deposited onto a transition metal layer and then transferred to a pcb or other substrate; optionally, patterned before or after transfer; alternatively, a seed layer may be patterned before or after Cg deposition. ALD processes have been identified for some transition metals, such as copper; see Wachtler Ph.D. thesis.

As used herein a transition metal is any element in the d-block of the periodic table, which includes groups 3 to 12 on the periodic table; the f-block lanthanide and actinide series are also considered transition metals. Please note the Wikipedia definition: http://en.wikipedia.org/wiki/Transition_metal [Sep. 30, 2013]; incorporated herein in its entirety by reference. However certain transition metals are not used in combination with certain semiconductors; these deleterious combinations are well known in the industry; the term “contact transition metals” is used to indicate acceptable combinations of transition metals and predetermined semiconductors. For example, preferred “contact transition metals” for Si and Ge are Ti, Cr, Co, Ni, Mo, Ru, Rd, Pd, Hf, Ta, W, Re, Os, Ir, and Pt. Copper and gold are frequently used as a catalytic substrate to grow graphene films; these metals are clearly excluded from use in the instant invention when Si and Ge semiconductors are involved; However Groups II, III, V and VI and function with other transition metals including Au and Cu. However when a non-semiconductor substrate is used, such as a pcb or ceramic substrate then all transition metals may be acceptable depending upon obvious constraints and criteria. As used herein an acceptable contact transition metal is one useful for the catalytic deposition of graphene, including its various allotropes, and one which reacts in a beneficial manner with a semiconductor or other substrate material of interest.

Conventional deposition processes may be used for forming contact transition metal seed layers and Cg layers; for example, physical vapor deposition (PVD), e-beam evaporation, molecular beam epitaxy, or sputtering; chemical vapor deposition (CVD), atomic layer deposition (ALD), metal organic chemical vapor deposition, MOCVD, plasma enhanced CVD (PECVD), low-pressure CVD (LPCVD) and molecular beam epitaxy, MBE; in some embodiments electrolytic or electroless deposition may be appropriate; conventional deposition processes are not limited to known techniques, but also include future deposition processes for forming a contact transition metal seed layer and Cg layer including additive processes comprising gases and/or liquids and/or solids.

### Definitions, Terms, Elements

As used herein graphene, Cg, is one of the crystalline forms of carbon, alongside diamond, graphite, carbon nanotubes and fullerenes. In this material, carbon atoms are arranged in a regular hexagonal pattern. Graphene is described as a one-atom thick layer of the layered mineral graphite. Please note the Wikipedia definition: http://en.wikipedia.org/wiki/Graphene [Sep. 30, 2013]; incorporated herein in its entirety by reference.

As described in Wikipedia, bilayer graphene is two layers of graphene. Bilayer graphene typically can be found either in twisted configurations where two layers are rotated relative to each other or a graphitic Bernal stacked configurations where half the atoms in one layer lie atop half the atoms in the other. Stacking order and orientation greatly influence the optical and electronic properties of bilayer graphene. A three-dimensional honeycomb of hexagonally arranged carbon is termed 3D graphene. Xue, et al., have postulated, by molecular dynamic simulation, allotropes of graphene which they term “graphyne”, in three configurations, α, β, and γ; as well as graphdiyne, graphyne-3 and graphyne-4. As used herein the notation “Cg” will refer to graphene and its allotropes in their entirety, single and multilayer.

A graphene layer, Cg, may comprise a single-layer or multiple-layer carbon structure and may be formed by processes previously mentioned or micro-mechanical stripping and bonding transfer thereof, or other appropriate techniques, known or to be developed.

As used herein an electrical interconnect network refers to the electrical network of an integrated circuit and the electrical network of a printed circuit board and the electrical network of a metallized ceramic substrate and flexible substrate or any configuration wherein a substrate comprises solid state devices electrically interconnected to each other and wherein at least one connection of the electrical interconnect network comprises a contact comprising Cg.

While the exemplary embodiments and the advantages thereof have been described in details, it shall be understood that various changes, substitutions and modifications can be made to these embodiments without departing from the spirit of the present invention and the protection scope defined in the appended claims. As for other examples, it shall be understood by those skilled in the art that the order of the process steps may be changed without changing the protection scope of the present invention.

In addition, the scope to which the present invention is applied is not limited to the process, mechanism, manufacture, material composition, means, methods and steps described in the specific embodiments in the specification. Those skilled in the art would readily appreciate from the disclosure of the present invention that the process, mechanism, manufacture, material composition, means, methods or steps currently existing or to be developed in future, which perform substantially the same functions or achieve substantially the same as that in the corresponding embodiments described in the present invention, may be applied according to the teaching of the present invention. Therefore, the appended claims intend to include said process, mechanism, manufacture, material composition, means, methods or steps in the protection scope thereof.

In using this concept certain design rules must be established for through hole sizes, isolation material and separation distances from active components. These rules are a function of the minimum feature size of the integrated circuit and overall process capability of the particular manufacturing facility. The semiconductor device structure mentioned above is for illustrations only. Other detail features may also be added, such as well implant, halo implant, spacer, stress liner, etc. One knowledgeable in the art can easily establish appropriate requirements.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

Foregoing described embodiments of the invention are provided as illustrations and descriptions. They are not intended to limit the invention to precise form described. In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by this Detailed Description, but rather by Claims following.

I claim:

1. An electrical contact to a semiconductor comprising;
a first contact transition metal layer; and
a graphene layer, Cg, wherein the first contact transition metal layer makes the electrical contact to the semiconductor and the graphene layer is deposited onto the contact transition metal layer.

2. The electrical contact of claim 1 further comprising a second contact transition metal layer overlying the graphene layer, Cg.

3. The electrical contact of claim 1 wherein the electrical contact is ohmic or a Shottky diode.

4. The electrical contact of claim 2 wherein the first contact transition metal and the second transition metal are substantially of the same composition.

5. The electrical contact of claim 1 wherein the graphene layer, Cg, is deposited by a process chosen from a group consisting of additive processes comprising gases and/or liquids and/or solids.

6. The electrical contact of claim 2 further comprising a second graphene layer, Cg, and a third metal layer.

7. A solid state device comprising;
a plurality of electrical contacts at least one of which is the electrical contact of claim 1; and
an electrical interconnect network comprising a contact transition metal layer and a graphene layer, Cg, deposited on the contact transition metal layer making electrical contact to the electrical contact of claim 1 such that the electrical interconnect network connects at least the electrical contact of claim 1 and one other electrical contact of the solid state device.

8. A substrate comprising;
a plurality of electrical contacts; and
an electrical interconnect network comprising a transition metal layer and a graphene layer, Cg, deposited on the transition metal layer making electrical contact to at least two of the electrical contacts such that the electrical interconnect network connects at least two electrical contacts of the substrate.
